(19) United States
(12) Patent Application Publication
(10) Pub. No.: US 2025/0137392 A1
(43) Pub. Date: May 1, 2025

(54) Attenuation means for emission neutrality/harmful emission control "k"

(71) Applicant: Colin Butterworth, Launceston, Cornwall (GB)

(72) Inventor: Colin Butterworth, Launceston, Cornwall (GB)

(21) Appl. No.: 18/835,600

(22) PCT Filed: Feb. 2, 2023
(86) PCT No.: PCT/GB2023/050227

§ 371 Date: Aug. 2, 2024

(30) Foreign Application Priority Data
Feb. 3, 2022 (GB) 2201402.1
Feb. 2, 2023 (WO) PCT/GB2023/050227

(51) Int. Cl. F01N 3/00; F01N 5/02; F02M 25/08; F16D 65/00; H02S 20/30; H02S 40/44; H10N 10/13

(52) U.S. Cl. CPC F01N 3/005; F01N 5/025; F02M 25/0854; F16D 65/0031; H02S 20/30; H02S 40/44; H10N 10/13

(57) ABSTRACT

A series of systems are disclosed for the capture of harmful emissions, and subsequent use of the captured gasses e.g. in combustion. Engines or other combustors are operated to increase the production of more useful emissions such as Carbon Monoxide CO and Oxides of Nitrogen NOx. Also disclosed are methods for using wasted heat from engines, brakes and shock absorbers, and for cooling solar panels for increased efficiency. Fuel pumps are disclosed with additional tubing to remove captured exhaust from vehicles, as well as supplying additional vehicle fluids. Monitoring systems may track emissions reduced or removed, and may be used as an accreditation/trading system.

### BACKGROUND

The present disclosure relates to a series of interrelated elements from the capture of exhaust gases and heat from combustion in addition to safety elements and fuel conservation and waste/exhaust treatment. With the intention of using those gases, once captured, and also combining/transforming/using the heat from several sources (exhaust/brakes/tires/engine/cooling/etc) and creating a usable energy. The aim of “Gas Guzzler” is to make harmful emissions and heat waste a thing of the past. Additional aims of the invention are: the capture of brake dusts that presently form a very dangerous by product of vehicle braking; the creation of a vacuum to the rear of the pistons to achieve maximum power and remove the current unnecessary compression behind piston with alternative piston types also; alternative usage of same said currently unnecessarily compressed gas for power gain with addition of minimal weight; pistons of new design to make use of the to and fro action of piston; behind the and also monitoring and control system to quantify the products created. There is a vast amount of coal power electricity generating plants across the world, the fuel is affordable and plentiful, however, the emissions (and loss of heat in trying to “remove” these emissions) are a major cause for concern. Energy and its use, be that vehicle, electric generation, heating and so on, has become a major issue, from its emissions a great amount of the total world GHG emissions occur. High heat stripping systems and consequent use of heat for the generation of usable power (vehicle, wood/biomass burning devices, power plant, computer, computer servers, data centres)

The subject matter discussed herein and within the background section should not be assumed to be prior art merely as a result of its mention in the background section. And thus a problem mentioned in the background section or associated with the subject matter of the background section should not be assumed to have been previously recognized in the prior art. The subject matter in the background section merely represents different approaches, which in and of themselves may also correspond to implementations of the claimed inventions.

### SUMMARY

Further areas of applicability of the present invention will become apparent from reading the detailed description provided herewith. It should be understood that the detailed description and specific examples, while indicating the preferred embodiments of the present invention, are intended for purposes of illustration only and are not intended to limit the scope of the present invention.

Gas Guzzler has been a name synonymous with the rapid and unfettered use of natural resources, but with this invention it is hoped that will change. The essence of the Gas Guzzler (GG) system came from the realization that realistically for the next decade or so (and beyond possibly with this invention) fossil fuels will form a major role in the “energy” system of the world. There are other ideas for how to power the worlds needs but these too come with issues: nuclear energy has nuclear waste; solar has space, intermittency and efficiency issues; wind has similar issues to solar with visual objections and concerns over wildlife impacts. And so energy production is, pros and cons, trade offs and impacts. Fossil fuels are at this point in history are still relevant as the technology to replace it isn't there yet, one day maybe very soon, but not right now. So rather than hoping that one day it, the technology, will come and ignoring the impact that massive emissions are having right now Gas Guzzler seeks to bridge that gap and answer a few other problems along the way.

The subject matter discussed in the background and summary sections should not be assumed to be prior art merely as a result of its mention in these. These parts described can be used all together or individually for best result and are covered by this patent. These embodiments are not intended to limit the scope of the claimed invention, but rather these embodiments are intended only to provide a brief summary of possible forms of the invention.

### DESCRIPTION

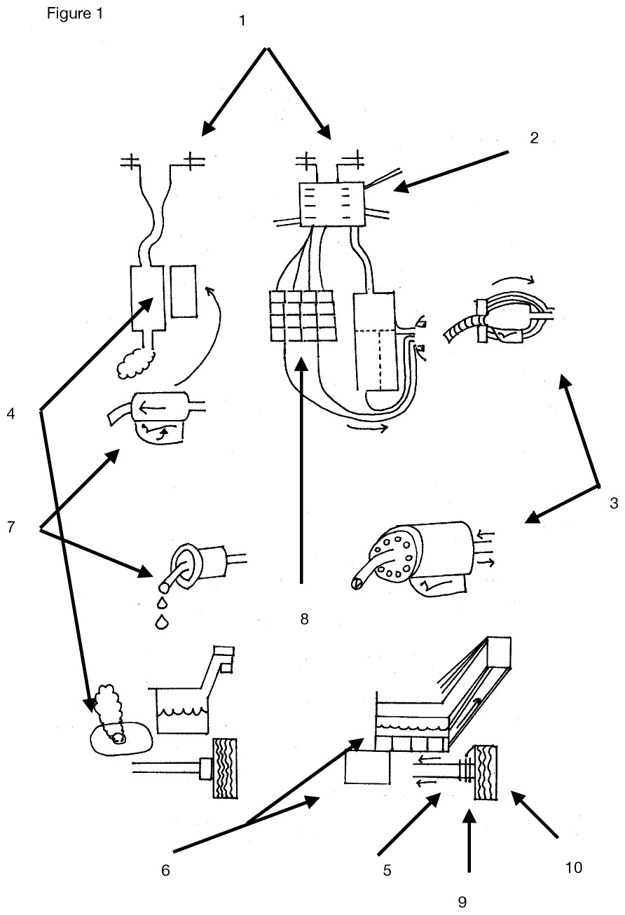

### “The Gas Guzzler” (shown in FIGS. 1/2/3/4/5/6/7/8/9/10/11/12/13/14/16)

The first issue that GG seeks to tackle is that of emissions, the burning of fuel results in exhaust and or byproducts and GG's primary role is to deal with this. GG will capture these exhaust gases at source (car, motorbike, tuk tuk, truck train, tractor, ship, helicopter, plane, house, fireplace, office, commercial, industrial, anywhere there is a fuel burned and exhaust gases) and transfer, store and or treat them. Any combustion resulting in exhaust is somewhere GG can be used to eliminate or reduce exhaust as required.

These gases can then either be used at collection, onsite or taken away to a refining centre to be split up into its basic or salable parts.

For vehicles, as an example, some very good sites (but by no means the only sites on vehicles) for the GG could be in the space formally needed for the muffler/exhaust assembly (that space not being needed any longer as the exhaust gas is now being captured, by GG, for use/delivery and the heat being sent into the energy harvest element of GG (see “CHS”) or indeed a new tank on the underside of the vehicle or perhaps a “sharing” of the fuel tank space via some sort of separation or similar. The transfer of the products of GG from the stored state is of importance. This is, perhaps, done via a “Pump and Dump” function whereby, during the intake of fuel, a secondary set of systems are activated that take the products from the producer (in this example the vehicle). In the case of a vehicle, for example, during the “fill-up” of fuel a virtually unnoticed thing happens in that as the fuel is transferred to the vehicle the collected exhaust gases are drawn up separate pipes to be stored perhaps with in the underground fuel tanks or atop the gas station/fuel store or back into the filling vehicle/tanker/tank. At the same time, if desired, produced pressurized gas(es) and or electricity (see CHS later) could also be drawn away to the grid, home, batteries or the like.

Another type of solution to the storage and removal of the gas(es) could come in the form of a stand alone tank, similar to the refillable bottles for propane/natgas or indeed CO₂. These would have the benefit of allowing flexibility to the system and a separate method of control. In a way similar to the swap out tanks for gas(es) a battery swap out for filled batteries could be made. In the case of the exhaust gases these could then be transferred via pipe to refining centre(s) (onsite or otherwise) or indeed taken away in the very trucks that bring the fuel (with modifications) to the fuel store.

There are several ways to achieve the transfer of the exhaust, gas(es) and or electricity and other products from the vehicle to the storage/transfer/use place and they fall vaguely into three embodiment types, above, below or to the sides (inc front and back). A very tidy solution, as mentioned, comes in the form of the already being connected hose to fill the fuel tank, if this were modified or built new in the factory it could measure and monitor at the same time as the fuel is being pumped in and also take out the products along lines that run alongside the existing pump hose.

The weight could be kept low to not impede use and people are already able to accept change in the pump design as evidenced by the recent introduction of disposable glove holders to pump handles.

The vehicle could be fitted with new “smart-collar” around the fuel nozzle hole that would lock it (locking optional) in place during use, exclude wrong fuel use (the smart-collar could be fuel type specific), monitor in and out flows of fuel/gases/electricity/etc, with a similar new smart-collar being fitted to the handle side to lock-on and tally information and relaying of said information to rest of the system where needed. Pipes from the onboard storage tanks/batteries could be run and the outlet installed beside/around the existing nozzle hole through the new smart-collar, this has the advantage of no new holes to the exterior of the vehicle so impact, visual or otherwise, is kept to a minimum (new dedicated holes could still be created if so preferred). There is an invention for the separation of fuel vapours for sending for use in the engine. GG could provide a similar safety feature by drawing the fuel vapours out of the vehicle at the same time as the fill so as there need be no alteration to the engine or add weight by another onboard tank. The fuel vapour could be used/condensed and accounted for under Gredits System (see Gredits later). Overhead systems are a possibility of course for GG attachment “hoses”, underneath is also a possibility too. A fully automatic connection system could be a preferred method for some situations and this being an embodiment. Certainly GG can capture and/or separate (into constituent parts/gases) any kind of exhaust, from vehicles/power stations/buildings that emit now, to any other type of exhaust for either sequestration, treatment or separation. A similar system of exhaust containment and transfer from other buildings (home office or the like) is also envisioned. The piping for this would need to be built but there would be many instances where this could be tied into the piping for the capture and transfer of emissions from the heating system or localized electricity generation.

This collar system would also have the very handy use of being able to fill up all onboard liquid and gas levels to the correct levels without having to manually do so. The window washer and oil levels and cooling system could all be maintained without so much as lifting the hood. As whole vehicle fluid and gas system could be maintained through this system. Is so desired several pipe systems could be made to act in this function, but the premise of having a whole vehicle fluid/gas monitoring and top-up system through minimal interaction from the user would result in a easier and more accurately maintained system as it could be done in a near automatic function.

Another function of these new handles would be the addition of a “Drip Free” end that doesn't allow for the waste of fuel at end of fill. It could be as simple as partially covered ends to the pipe to a fully closing end to the pipe. These advancements would equally apply to other pump and pouring devices including hand held fuel cans.

As a part of this redesign of pump handles a specific sub system of anti spark systems would be sought to be added in. The risk of spark and consequent explosion at fuel stations is mitigated as much as possible and with this new style of handle the risk will be further reduced as the fuel will only be dispensed once a secure lock is obtained and fuel vapour is sucked away for condensation (reducing the amount of available fuel for fire) but to add another layer of security actively reducing the risk of sparks is desired. This can be done in several ways including covering the ends of the pumps on spark-less material (plastics, wood coatings, fabrics etc all of which could be made to be easily removed and then recycled). Another such embodiment of this spark-less design would be an active interaction between the pump handle and the vehicle whereby the two are linked and a “grounding mechanism” is established so that any static discharge is “captured” and focused in/through a safe route up and along the pump handle and pipework. This would give an extra level of security and reason to upgrade from existing equipment thereby garnering the other benefits of the overall system (these anti-static elements could however be retrofitted/installed on “old style pumps” should the need be so).

Whether canister format, piped or with tanks all require a robust safety system(s) in place to deal with any leak and or over capacity issue. This could be as simple as warning bell or a backup/reserve tank, or further on a shut down sequence or a direct vent bypass, all of these would be monitored so that the situation can be resolved in a speedy and safe non polluting fashion.

Another element for the energy harvest is that of pressurized gases from pressurizing the exhaust gases and or from the running of the electrical generators. These systems once in-place could also be used for the pressurization of air and other gases as well if so desired. Pressurized gas is a wonderful storage method for energy and could be a helpful component to the GG system with connection through the Pump and Dump to deliver the energy on or off the vehicle. The pressurized gas could also act as a major energy component to the motive power of the vehicle, the ICE engine providing, through the GG system, the fuel for its own “hybridization”. This system of pressurizing gas as a use for waste heat from power stations and from the heating of buildings ties in with the rest of the GG system.

High temperature electrolysis using the heat from the exhaust is a useful way to transform the heat energy into a usable energy product (see CHS).

Another advantage over the current system of catalytic converters (“CC”) is that the GG system would be made such as to not create “back-pressure” as can happen happen with CC system thereby hampering engine efficiency. This could be achieved by “drawing” the exhaust away into the GG system. This could be designed to give the best “draw” and thereby the best fuel consumption. There is also the added benefit for GG over CC of not needing the “warm up” period that CCs need before coming up to the right temperature and working properly, thereby saving these emissions that would, and are, otherwise still be(ing) emitted with a CC. The GG system could, of course, be made to work along side CCs to capture those emissions at the very least and quite quickly.

In the case of homes, offices buildings or the like the emissions from power production and heating these could be stored on-site for pickup via fuel truck, either the one that brings fuel or dedicated type or indeed piped direct to a refining centre. If the goal were to make NOx and CO and have these as valuable products rather than being charged as a polluter now and into the future individuals and businesses, and government for that matter, would most likely choose the rewards of the GG system (or parts thereof) rather than the penalties associated with pollution (financial or image damage being examples).

### “CO-NOx the Problem” (Shown in FIGS. 1/4/5/7/8//9/10/12/13/14/15/16)

The second issue that GG seeks to deal with is what kind of emissions are made in the first place. Certainly in the case of vehicles there is good news, if the very expensive catalytic converter system is done away with, and the focus is put into the production and not the destruction of the NOx group of compounds and the saving of CO (carbon monoxide) also. As these, CO and the NOx group of compounds, have uses. The NOx group have toxic effects on humans at ground level when emitted from the exhaust of vehicles so catalytic converters were invented to alter them to a safer compound, ie CO₂, which although made the air we breath safer, its effects on the atmosphere are beginning to show in the now widely accepted theory of global warming. The large scale release of CO₂ has lead to many questions about how to decarbonise emissions and or deal with them. Although CO and the NOx group of gases are the preferred target for GG it can capture the existing style or variation of exhaust and transfer that in a similar way for use/treatment/sequestration. Patents U.S. Pat. No. 9,175,591 and US2019170046A1 are non-limiting examples of CO₂ capture systems as these seek to capture only CO₂ and use this as a fuel additive—the do not take off the CC for capture of the undiluted exhaust or the alteration of exhaust (with NOx and CO being deliberately pushed for) as GG does. As they also state CO₂ is quite stable and expensive product to sequester or transform, whereas if using GG to target obtaining CO and NOx on the other hand these can form a valuable part in the economy of the world as CO and the NOx group of compounds have many uses. Good examples being the N in NOx being nitrogen which forms a major constituent part of fertaliser or using NOx to replace air in part of a combustion process for better fuel efficiency. If onboard cracking of water is achieved using the waste heat of the ICE and onboard electricity then this could be combined with onboard produced (or taken onboard at “fill up”) then these could be combined using a pressurized tank to create ammonia.

Another interesting operation of the catalytic converter is the destruction of unburnt hydrocarbons into CO₂ and water whereas in the GG system these can be collected and either separated/processed and burned onboard or sent out for processing. These also have the ability to be specifically captured for the alteration and use in the production of ammonia. As happens now hydrocarbons, mainly methane, are used as a feed stock and altered with heat and the addition of nitrogen to form the useful and stable ammonia. Using unburned hydrocarbons from the ICE could provide an alternative source of the highly versatile ammonia.

CO has perhaps the most exciting part to play in this invention. CO can be burned and indeed has been used extensively in the past to power vehicles with using it as part of a syngas (one such example is called “wood gas”). The use of a catalytic converter seems odd in this age of fuel concern and waste reduction when we can capture, purify, store, transport then use (burn) the CO to produce little more than the CO₂ that is created by the catalytic converter. The amount of energy that is being willfully destroyed by use of the catalytic converter needs to stop and instead put the CO to use to reduce the worlds energy concerns. The CO could be burned or put (along with other gases captured) towards a system like the Fischer-Tropsch process where a conversion of a mixture of carbon monoxide and hydrogen often with a metal catalyst into liquid hydrocarbon. The heat of CHS could be used as the temperature that is needed to achieve good results as (in at temperatures of 150-300° C. or 302-572° F.) it could also make use of hydrogen produced on board. The production of a syngas is also an embodiment within GG using the captured carbon monoxide and other gases along with produced hydrogen. The GG system could, using heat from the exhaust etc, to separate and store onboard the gases, for transfer or indeed use onboard, could create a wide range of gases etc for many uses. This although discussed in relation to vehicle is relevant to building/power burning of fuel and their emissions (with evaporative cooling as a useful way of increasing the energy harvest).

### “Central Heating Power” (CHS) (See FIGS. 1/2/3/4/5/6/7/8/9/10/11/12/1314/15/16)

The next issues that GG seeks to answer, and it is a major one, is that of the byproduct of heat from the burning of fossil fuel. Heat byproduct can make up two thirds of the initial imbedded energy, or to put it another way for every unit of energy you are able to use, two are wasted as heat. GG aims to redress this imbalance by taking this “wasted” heat energy in the exhaust and combining some or all of it with other heat sources like but not limited to that of the braking system, engine cooling, vehicle body cooling, A/C (heat pump), solar panel cooling, and the heat from the wheels and from friction of the tires into a “Central Heating” system. Combining these heat sources into one system allows the harnessing of all/most of this heat energy and by several processes run in succession (including but not limited to: high temperature electrolysis; electric steam generation; integrated multi-layered steam electric generators [inc cluster style]; automotive thermoelectric generator (ATEG); phase shift in water—this allows the harvesting of as much energy as possible for either use on board or for connection to the grid or home use. The harvest of heat energy and its use could provide a major reduction to the overall energy requirement (and thereby heat emissions) of ICE using machines, reduced costs for fuel and environmental damage could be expected. Further function of being able to hold on to (store) residual heat for transfer once vehicle stopped for other uses (hot water/heating/further heat accumulation and use [eg electric generation]).

Either one or several larger steam turbines or indeed a cluster of smaller ones could be fitted on all the CHS systems whereby the heat energy is converted into electric energy via the steam turbine. This electricity can then either be used onboard/site or directly into the grid or stored for transfer at a convenient time. A possible connotation of this with regards to these generators inc “cluster type”, where many small turbines are created to work together, would be a “factory built” (scale of economy is an issue in the vehicle manufacture business so would be looked to be replicated with these) and made specific to the type and power of the vehicle being fitted to (generic [cheaper perhaps] types are also possible). A specific style of cluster type could be one that could bolt directly to the underside of the vehicle. It could be custom made or batch made and sent direct to the installer like any other commonly available part it could bolt over the underside of existing vehicles or straight into new vehicle production lines (a specific lift kit to raise the vehicle could solve space issues). If there is space the cluster style could sit alongside the GG tank(s) and similar for the larger, lower numbered, system of turbine(s) idea used could also be configured to fit alongside/near the GG tank in the former muffler/exhaust space or within the engine compartment perhaps where the radiator currently sits (as its function could be replaced by GG and the evaporative cooling embodiment [see Water Uses] etc.) or elsewhere within the vehicle depending on vehicle and manufacturer.

The phase shifts from water to steam at each stage offer more opportunities where electrical energy can be harvested. Using the electricity created on board it could be used for motive power or stored or it could indeed be used to split water into its constituent elements of hydrogen and oxygen via electrolysis and again either for use/storage/transfer or combining with the CO to create a Syngas or a liquid hydrocarbon. The high temperature electrolysis method offers a very exciting opportunity to use several energy harvesting methods in combination to obtain good results (see Water Uses). The use of evaporative cooling also offers a chance to use an automotive thermoelectric generator (ATEG) that relies on the temperature difference, cold created via the evaporation process and heat from the contributors to CHS, to also create electricity.

The ability to store hydrogen poses many issues. From hydrogen embrittlement to the risk of leak and its flammable nature. There exists now an opportunity if the hydrogen is split and then drawn in with nitrogen to form ammonia. This ammonia is stable and of great use.

An offshoot embodiment of the above is a solar panel cooling system that would also be for the harvest of usable heat energy for hot water (domestic or commercial) or for the accumulation of this heated water to combine and be used within a electric steam generation system. Solar panels function better, somewhat ironically seeings as they are often black and designed to capture sunlight, when they are not hot. So it would be an efficiency gaining mechanism for the solar panel itself and an inexpensive form of hot water as a “by-product”, with the uses of that heated water giving further energy savings as other forms of energy use to heat that water are avoided. When applied across the world a very large amount of energy could be avoided being used that is currently being used to heat water. The system could also be designed to used the heated water or steam for electricity generation then use the remaining still hot water for domestic/commercial needs.

With relation to the power generation and energy saving of use of evaporative cooling there is another embodiment that exists. The use of tubes mounted to the vehicle (or building) that air would be able to travel down. This would be able to cool large surface areas within the confines or the space allotted and have a minimal effect on speed loss. These pipes could be mounted to the base, sides or roof and allow a simple flow through (although more complex routes are envisioned, weighing up benefits of these will be up to individual application) that would provide a cooling action to the pipes that could be harnesses for onboard cooling or indeed used for energy generation. This cooling could be amplified in effect by the addition of and evaporation of water (liquid). With phase shift actions (gas to liquid to gas) occurring where possible for maximum energy harvest with minimal energy costs. These tubes could function in simple format to cool truck trailers and ships contents and car/vehicle interiors. In more complex embodiments these would be tied into the CHS directly and have a direct effect on energy use as cooling and motive power costs would be reduced. Where radiator exist today on the front of engines and take a usable energy and destroy it by simply cooling a hot engine and at the same time creating a dramatically un-aerodynamic shape in order to function this GG system will by contrast use that heat for positive gains and if needed channel air through these aerodynamic channels for cooling needs (be they simple cooling or more complex versions). These cooling pipes “style” however would have a real use with vehicles that are of the existing design (of radiator design and use) and could be retrofitted (under the body or carriage would be simplest, perhaps). Being able to close off the engine compartment rather than having to allow vast amounts of air to “run” into the radiator to cool the engine would have an appreciable effect on fuel consumption.

The shock absorption of vehicles also has application within the remit of GG in the fact that the shocks being absorbed are indeed energy being absorbed. This energy could, and should, be harnessed. GG deals with this in several ways. Firstly the energy can be harvested as heat energy and fed into the CHS system, so rather than just springs to take out the action of the shock there would be systems put in place to actively turn this motion into heat energy that can then be pumped or pushed into the CHS system (the system could even have “plate heat transferrers” built directly into the shocks to take the heat straight out. Friction or resistance to movement giving a good route to this heat creation, and these shock “heat generators” due to proximity would tie nicely into the wheel and tyre heat harvesting elements of the system. The second energy harvest method that is within GG is the pumping action of these shocks and these can be this pressure creation would be of great use with in the other subsystems for the creation of ammonia for example. Once the pressure is created then there are other places where it can be used (adding pressure to the pressurized gas tanks for either use onboard or for transfer for use elsewhere). Thirdly the shocks themselves would due to their repeated actions be able to have electricity generators fitted to them (acting as a part of the shock dampening system also or indeed simply added atop to harvest the action). It is therefore possible to harvest energy from the action of vehicle shock absorbers in three distinct ways and these can also be fitted to work together within the system.

Of further use of this CHS type of system comes in the form of computer cooling (inc data centers). Computers through their use create a byproduct of heat, this leads to a loss of productivity in computing terms. The current plans for this is to try and strip heat away from the computers via, generally, air or liquid cooling methods. This works well however there lies a better option in the form of GG—using the CHS style of high heat stripping ability and accumulation (or direct use) then taking this gathered heat and running it through systems to generate usable energy. These systems could then be used to feed the “grid” this energy or electricity or indeed offset the energy costs of running the cooling and operation of the computers in the first place. If computers are viewed as “engines of computing” then it is logical that the GG and CHS systems apply to them and their heat related issues—and more importantly the answer to them. There has been a shift of late to “Green Data Centers” and this works well (placed in cold locations to counter cooling costs), however the application of GG and the computer cooling and energy harvesting element of it allow for the reduction of overall energy consumption regardless of area of emplacement (there will still be preferable areas for them). With cooling ranging anywhere from 10%-45% of the total costs of running a data center any reduction of costs (and of course emissions) that can be achieved would be a welcome thing. With data centers using upwards of 2% of total US electricity consumption the application of GG and its consequent lowered energy use would have a positive effect on GHG reduction and company bottom-lines too.

Evaporative cooling is also an element of GG that needs specific mention in regards to computers and cooling. The creation of a system that uses the principles of evaporative cooling in relation to heat from computers and computing allows for a new direction in the cooling of computers. Rather than liquid cooling with its drawbacks or air cooling with its limitations where evaporative cooling is used it offers a middle route, and one that can potentially reach more areas of the computer and its areas that require heat reduction. This type of computer cooling could also be tied into the dehumidification of air around computers as this over humid air can lead to degradation and salt deposits on the circuitry. “Dehumidified” air and water to run the evaporative cooling system in one.

### “Brake Dust Sucks” (Shown in FIGS. 1/2/3/4/7/8/10/13/14/16)

The next issue that GG can deal with is the very exciting opportunity that could, at the same time as adding in the system to strip the heat out of the brakes, is to adapt that system even further. Creating a system to actively function as a filter, whereby the brake dust is filtered from the air and not released direct into the surroundings.

This filter(s) could be fitted without the other elements of the system. Although this sounds like a minor element to the invention it has some major health benefits and will make a very positive impart on air quality, which GG is focused on as a system.

A prime example of where this could be used and why this part of the system could be a major aid in the pursuit of cleaner air is the London Underground who have given their cleaners and staff magnetic “wands” which they wave around to capture particulate in the air from the brake dust of the tube trains.

Although this has an effect, how far better to trap this toxic dust at source before it travels deep into the environment and our lungs. The system would be based on the fact that much of the dust can be trapped via magnets and then post that other filters could be used if deemed necessary. If these magnets, followed by other air filters, were installed directly around the brakes and or within the air flow of the brake dust they could be fitted to any style of vehicle, new or old, and have a huge impact to these toxic releases. If all vehicles (be they trains, planes, trucks cars or vans—if it has brakes and during their use dust is released then this is a relevant embodiment of GG. Indeed this style of exhaust interaction and metal stripping relates to the exhaust mining element of GG. These filters and magnetic cleaners could have self clean options or commercial options to automatically clean them, during fillup or stand alone, with the usable metals etc recycled.) were to be fitted with this element of the invention many lives could be saved and the economy saved from the treatment of associated respiratory illnesses.

Of also consideration of this system is the heat that can be harvested by this element of the system (sent into the CHS or similar). This heat stripping carried out from not only the brakes, but also from the wheels and also the tyres giving better operation for these too. Active heat management of the tyres/wheels could be used as a source of usable heat energy and add a valuable amount of energy to the CHS. Heat could also be pumped into the tyres during cold starting conditions and the like in order to achieve best operation.

Plates to front or back of the wheels could form a basis for the emplacement of several functions within the GG system (“GG Great Plates” GGGP). They could house the brake dusts “sucking”, filtration and magnetic elements and also draw in the heat from these for use within the CHS or similar. They could also be used for the convenient stripping out of heat from the wheels and tyres. In addition to this they could if so desired and called for in specific design be fitted to generate power from the juxtaposition of fixedness and proximity to rotation (often high speed). This imbalance in speed offers a very real opportunity to harvest usable energy.

The fitting of these plates to the front and the rear of the wheel/tyre offer another energy harvesting situation. The wheels themselves are one of the largest areas of drag upon a vehicle, with these plates fitted the streamlining of the vehicle is achieved. The air rushing past has a negative (speed-wise) interaction with the counter-rotating rushing air caused by the wheel operation within the wheel arch. The plates fitted separate the two streams of air. With a simple “slide” or “swing” out of the way tyre changing is unaffected. In this there is a massive overall saving in energy use. There also from their use is the opportunity of the now (partially) enclosed wheels and their air movement. If this air is looked at as a resource now, rather than simply a aerodynamic drag, then the ability to harness that steady and definite flow of air creates a real energy harvesting situation, whilst at the same time reducing the pressure upon the wheel and tyre to move through the air in the arch. The air could be focused and made to power electrical producing devices/used within the evaporative cooling functions of the vehicle/put towards pressure creation devices/etc. All of these relevant to any form of vehicle and even on wheels without brakes.

At the same time as this type of air filtration it could also be turned towards the capture of tyre degradation. The loss of tyre material forms a major pollutant to rivers and also air pollution, it is therefore an element of this system, as there is already an air filtration portion to it, that air from around the wheel/tyre be drawn in where practical and filtered/cleaned. Again these particles can be filtered or used onboard or indeed taken off at interval, with connection via the Pump and Dump system a possible route.

### “Eleven Series” inc “Power Takeoff” (Shown in FIGS. 1/2/3/4/7/8/13/14/16)

A safety system that could be installed at similar time to brake dust capture systems that would be for the safe retention of wheels/tyres and should wheel-nuts work loose or be installed incorrectly. All these can be fitted with a key-lock system in addition for added security and safety. One or more of these systems could be fitted and having these could avert disaster.

Firstly a clamp-on (with various methods of attachment envisioned) inner secondary (or functional if in isolation) hubcap or “Snub-cap” would hold the wheel firm with direct linkage to the axel end. This would hold the wheel in place even in the event of the wheel nuts working loose. This would also safely contain the wheel-nuts should these come free.

Secondly a coiled wire (CW Sandwich) with one end attached to the axel and the other to the rim that, although would not stop the wheel leaving the axel it, would stop its uncontrolled flight from the vehicle. This element would be fitted to sit between (or around) the rim and the axel stub.

Thirdly a spring-loaded locking mechanism that the installer uses like a lock, tumbler and key like, and rotates the rim until in place then finding the gap through it and twisting against a spring that then pushes the rim back thereby locking it (known as “Spring Keyling”).

The fourth safety element is several fold in that not only does it function to keep the wheel/rim in place is several ways it can also be used to generate energy (“Power Takeoff”—both or either heat and electric). This fourth method (generally known as “Power Takeoff”) would be fitted to the axel housing (or on/within the vehicle itself) behind the axel stub, this would give room for installation and the arc to the rim/wheel. The device would consist of a “bolted on” device that would have a spool similar to the one fitted between the rim and axel stub. This one however would need a receiving channel to the rear of the rim that the end of the spool would slot into. Should the wheel come free this spool would run out but keep the wheel within the confines of the vehicle. While it is not being used as a safety device however there is the opportunity to use this device and design to either generate usable heat to feed into the CHS or similar or indeed be used as a dedicated electricity producing device. If the end were magnetic and the back receiving channel coiled copper wire (to the middle anyway) this could be used as an electric generator, feeding back into the vehicle for use or storage. Devices like this with the express purpose of electricity (or heat or pressure) generation are an envisioned embodiment of this element of the system. There would also be the ability to have an effect on tyre speed and therefore vehicle speed with this type of system, so there would also be able to be used braking (with heat taken into CHS desired) and speed control (including emergency “back-up” systems). Versions of previous that work to the “outside” of the tyre are also envisioned and these could be fitted with one per wheel or indeed many.

### “SEAICE”, “Bangbang Piston” and “Double Header Crosshead Piston” (FIGS. 1/6)

The fifth issue addressed with GG is the ICE engines piston chamber. Or rather the non combustion side of it. It deals with the air (or oil) to that side and indeed the removal thereof. If a vacuum could be created to the non-combustion side of the piston then on that part of the pistons travel there would be no resistance to the movement of the piston so therefore an increase in efficiency could be expected. By its very nature a piston has to be tight fitting and if this were applied to a vacuum creation as well a contained place for combustion both sides of the piston would be working for best use of fuel. This element being called SEAICE or Specifically Evacuated Assisted Internal Combustion Engine.

There also exists a power gain from the redesign of current piston design of ICE engines. The current design calls for a chamber to the top with inlets for both fuel and the exit of exhaust. The piston then travels downwards due to the explosive action with the chamber and travels back upwards to eject the exhaust. It is very efficient and releases a tremendous amount of energy that translates to motive power upon the crankshaft (or the like).

The first new style of piston (“Bangbang Piston”) appears like the existing pistons but with having a secondary combustion chamber built to the rear of the piston. This style of piston aims to use the already moving piston to preform the same task, but in alternate or opposite strokes. Or, when there is a combustion and expansion at the one side of the piston there is an air (gas with an oxidizer, NOx or pure O stream preferred) compression and fuel input to the other. Then with this compressed gas and fuel mixture there is combustion to fling the piston back the other way. Four stroke and diesel engines would use a slightly different format but the principle is the same—using the already moving piston to compress on the other side of the piston for the next round of combustion. So called Bangbang because there is a bang at either end of the pistons travel. The shaft to the back of piston could be straight downwards in shape dropping through the combustion chamber in the centre (other or more locations possible especially if these pistons are “hollow” and used for the transfer of heat/fuel/oxidizers/exhaust through the piston shaft itself) to the

The second new style of piston (Double Header Crosshead Piston) which looks like two regular pistons attached at the top of the cylinder head. This leads to the possibility of using every element of the cylinders travel for power production. The stages of the cycle devoted to compression and for exhaust clearing could be “powered” by the action of the cylinder to the other side. The already being created explosive force of this other cylinder would be used for these functions rather than using power from the system thereby diverting it from powering the engines power output.

These designs may be coupled with the “CHS” mentioned above and for the active removal of heat generated by the combustion. The cooling of the pistons, or the heat transfer, could be achieved in several ways including a vapour-compression cycle akin to AC systems and air source heaters. High heat and high flow pumps could be built into the sides of the piston chamber to draw large amounts of heat away quickly and once that happens that heat can then be used to create more usable energy. The heat using energy creation systems could even be built into and around the pistons' cylinder to achieve the greatest heat transfer for energy production (in some cases even powered by the pumping of the piston).

### “Water Uses” (Shown in FIGS. 1/4/5/7/8/9/10/12/13/14/15/16)

The sixth issue that is addressed within GG takes the water element that typically just exits the exhaust, and as all (or most) of the heat is taken out of the exhaust with GG and used it leaves a lower temp water for possible use (cooled stored used). This could be used within an evaporative cooling system to aid in energy generation via an automotive thermoelectric generator (ATEG) since the system relies on a temperature difference to function.

The evaporative cooling element of this system, and elsewhere where evaporative cooling is used, could be enhanced by the addition of a “Dragons Tail” style of design to the run of pipe that the evaporation and cooling takes place in. This would take the form of rather than a clear and smooth bored inner pipe surface (or surface being used) there would be areas of eddy, where as the air/gas travels past smaller amounts can be brought into the eddies zones for additional cooling. This would also allow for and area for extra evaporation space within the same length of surface. This would be of great use when trying to keep weight down (as in vehicles etc) or where space is at a premium (eg data centers or personal computers).

Further to the Dragons Tail enhanced evaporative cooling elements of GG are embodiments to also increase the working capacity of said systems. The first is a pipe (often set wit others in line or grid) to allow the flow through of air and give a cooling effect and also an area for running evaporative cooling. The second is a double helix style of pipework. This gives a higher proportion of cooling surface than the straight through pipe but would come at a cost in relation to “speed” if used on vehicles. It would also be able to be fitted around the straight through pipe to add extra cooling to that element should this be desired. The third is a “plate” style of heat (or cold transfer system that would be fitted so as to allow a steam of air to pass over it and be thereby cooled. These systems would work well in isolation but could be fitted in conjunction with each other to achieve a higher output. These are envisioned early on as being fitted (above, below or through) to cars, trucks, trains, ships and other vehicles to make a good use of the excess heat of their engines but have other static emplacement locations also—power stations and homes as well. Their use in the cooling of buildings would have a great overall effect to the energy consumption of building for cooling. Another use for the collected water could be in the electrolysis method of water cracking to make H and O. Temperatures that can be achieved within the GG system are a great aid to the cracking of the water via high temperature electrolysis into hydrogen, as the higher the temperature the more efficient the process. This hydrogen could be used onboard or stored for transfer or indeed combined with nitrogen to form ammonia.

A further use for the water also uses the evaporative cooling method but applies it to just that, cooling. It could be used to cool the interior of the vehicle cab or trailer to replace a proportion (or all) of the cooling cost associated with air-con and refrigeration, which when applied to the transportation industry would have massive energy savings. If this embodiment is used water drawn from the air (or other sources) and could also be fed into the evaporative cooling system so as to create very cost effective cooling system. Aboard ships (trains/trucks) is another desired embodiment as the space available (on-deck etc) and distance from other energy sources and proximity to water makes these especially useful for container ships, cargo, bulk carriers, LNG carriers or any ship. This lends itself well to this and if it were to be coupled with a solar panel it could provide a very cost effective solution and embodiment. These evaporative cooling and solar panel combinations also have uses elsewhere like atop trains(carriages) and trucks(trailers) and vehicles in general, of course an evaporative cooling system underneath these is also a desired embodiment. There are also uses for the water within the steam generators and in the phase shift of water to gain more energy from the exhaust. Another use of course for the water is to heat treat it, with either the exhaust heat or indeed the CHS, and have a pure source of water.

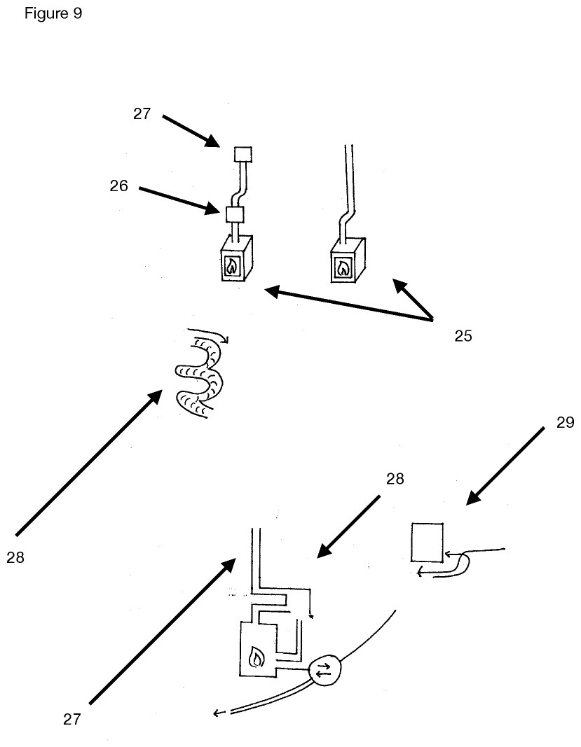

### “Fire's Place” (Shown in FIGS. 9/10)

Another embodiment of GG is to deal with the exhaust and therefore emissions that come from fireplaces/wood burning. The popularity of wood burners and their perceived “greenness” has lead to a large amount of them being installed which has brought to light several environmental issues created by their use. Namely they produce emissions, admittedly from a renewable resource, they also produce “particulate”. Design of fireplaces has improved greatly in recent times to bring these down however GG fits the next stage of the development. This is achieved by using the heat that would otherwise go up the chimney as waste and rather directing that toward the separation and capture of emissions and also the catching of particulate (as the exhaust gases/smoke are cooled then this can be run through several types of filtration system and repeated stages of filtration—made easier by the reduction of heat). Any residual heat could be of course be directed back into the building, having a positive impact on the amount of resources needed in the first place.

The capture of the emissions requires a route to take them out. This could be direct piping to carbon sequestration or indeed transport vessel/vehicle. The same idea could bring in oxidizers for the cleaner burn of the fire place, after much is made of a clean chimney this is needed as the creosote is unburned fuel. A creosote condenser and “burn-off” system is desired as this could not only reduce risk of fire use but also increase fuel efficiency as rather than losing the creosote up the chimney to remain unburnt with need to remove it but rather “flared off during normal operation. With recycling the “smoke” from the fire back into the burning chamber and then in some cases adding in either pure oxygen, NOx or the like then a fuller and more complete burn of the available fuel can be achieved.

There is also the issue surrounding fires drawing air from within the home/building. This uses air that is in the home to power the fire. There is, for fires of a certain size, the need to provide a venting into the room because these fire can draw so much oxygen out of the room it becomes a danger to those inside. The adding of a vent into the room provides the air but also a problem. Cold air. In adding the “vent” you are adding a hole in the side of the building and actively drawing cold air into the interior of the building thereby adding to heat requirement and the consequent fuel usage. This is sometimes addressed by the direct venting into the fire of outside air (or a combination of outside air and air still drawn from within the room). This is a fine solution, but it misses a point. The fire could be fed with air from the room, thereby taking indoor air which is often said to be much worse than outdoor air, but before it is fed into the fire it could be used to warm up (heat exchange) air coming into the building, fresh air. This has several functions: the air in the room is removed for clean outside air; the room air isn't simply dumped out side making outside air worse; the incoming air is warmed almost to room temperature so there no “drafts” felt; the majority of the heat can be transferred to the incoming air, but not all, so rather than just accepting that hat loss and dropping that heat directly outside the air is fed into the fire meaning the fire has a slightly elevated fuel stock of air so more heat can be fed into the room.

Akin to this embodiment is the addition of oxidizer into the combustion chamber of the fire/woodburner in order to increase the efficiency of the fuel use. The gases (NOx/oxidizers/O/CO could be piped in and fed directly into the fire/woodburner and with increased controls greatly reduce the amount of fuel needed, as the use of standard air limits the amount of oxygen available for combustion. It could be delivered in tanks or by truck or indeed piped all the way direct to the home. Fitting the system would require increased safety considerations as the but as fires already produce NOx homes are mostly already capable of dealing with these gases. Thought would be needed to ensure that the increase in efficiency is done in a safe and considered fashion and to ensure real gains in efficiency and safety in real world scenarios. Secondary NOx alarms and fire heat control systems would be desirable.

Emissions from logburners/woodburners/fireplaces taken into an exhaust heat stripping system to ensure minimum fuel usage. These trapped emissions are then fed into a tanking and piping system to be held and sent for refining. The use of specific burning heats and methods and inputs to “direct” these devices towards emissions containing as much NOx and CO as possible (trying to avoid ending up with CO₂ as this is too stable a compound, whereas the others can be used in a variety of ways).

Safety bypass system to ensure safe operation—use of the existing chimney would be an ideal route if being retrofitted, new chimney if new install

GG is able to tackle the emissions from biomass burning also, again from renewable sources but still emitters, by taking these emissions and capturing them at source so they can be treated. This system could allow green technology to advance that next stage, not just carbon neutral, but if the emissions are dealt with, carbon negative. A positive negative.

### NOx LocalMotion and power8ion (Shown in FIGS. 1/4/5/6/10/11/12/13/14/15/16)

Another important part of the GG system is the specific collection of NOx or sometimes NO (nitrous oxide) in specific, that is produced without the catalytic convertor being attached to vehicles. Adding a very real possibility for the massive reduction of fuel consumption.

NOx has often been used in engines to increase the efficiency of the fuel use and increase of power. Basically if NOx is used in the combustion chamber rather than standard air it will contain a higher proportion of oxygen than that in air so more oxygen is available for fuel burn. So if vehicles were modified to take NOx rather than air and a consistent source of NOx were available (from GG for example) then not only would there be a very large call for the NOx produced by the collection part of GG, but the very use of the NOx would be to lower fuel use and thereby lower emissions.

The combustion chambers that use NOx need to be stronger than those that don't as the power generated is much higher, but if the aim is use the NOx to reduce fuel use then this would be taken into account.

Diesel engines already in some cases pipe the exhaust back through the combustion chamber to use some of this NOx but GG could take that a step further and return NOx to the vehicle in a cleaned and pure state for maximum power. Indeed NOx could be added into anywhere the “fire triangle” of heat (pressure), fuel and oxygen is used (of which NOx has more O than air) so electricity generation could be a prime user of the NOx made by GG as they consume large quantities of fuel and the modifications of equipment could be done so on commercial terms. Indeed in situations like factories and power generation plants the “refining centre” could be onsite if economies of scale permit. Similar for ships, trains, homes, buildings, industrial, commercial, and trucks/large machinery etc.

The use or burning of fuel to create electricity is a major part of the world's electricity system. A major part of that system relies on massive power-plants that take in huge amounts of fuel burn this and then transport this electricity to the areas of use/need. This works well and homes are supplied with electricity. However. There is a huge amount of waste in this method of energy transmission. The majority of the energy (⅔s) is turned into heat and this is wasted, from what is left this enters into the grid system whereby another ⅔ are lost in transmission to electricity consumption. As can be seen most of the embedded energy used in the creation of electricity is lost far before the use in the home/building (with only ⅓ of ⅓ reaching the end user, or another way of putting it only just over 11% of initial embedded energy makes it use—so very nearly a staggering 90% is lost as waste). This could be addressed by the calibration of use and local production—so called LocalMotion. Diffuse electricity generation is a concept of producing local to need the electricity needed for that area, with GG this type of fuel (NOx and other oxidizers) this type of generation becomes all the more attractive. Fuel use leads to fuel price rises, therefore the less a country uses fuel the more affordable its fuel will be, therefore calibrating the electricity use and production more accurately and locally (with national grid back up) provides for an immediate (and vast) reduction of fuel use and emission generation. A new locally minded power production “plant” is therefore a part of the GG system that not only uses NOx or other oxidizers in combustion but also is designed to power the buildings in its immediate surroundings. So while being able to feed into the existing electricity generation power system and make it much more efficient GG also seeks to create a new way of electricity generation/use with these new small embedded NOx/oxidiser/pure-oxygen running power plants. In addition to the vast fuel savings it would also provide for a more secure energy system as it would be many smaller producers backed up by the grid as opposed to fewer larger ones which when they have a power production hiatus effect many homes/buildings, but also place major strain on the rest of the power supply system. This form of electricity generation has the added benefit of being able to supply the local community with the excess heat from generation. Heat doesn't travel tremendously well so while the large power plants do what the can to use this heat in the surrounding buildings it cannot travel as far as the electricity they generate. If the generation is local this is overcome as far as heating is concerned and with regards to hot water as well year round, it also allows for uses of the excess heat still generated during the Summer/peak times etc.

The capture of CO and NOx from coal power-stations emissions is a major goal of the GG system (power8ion). The use of coal powered stations to electrify a major part of the world is, for the foreseeable future, a given, as there has been a huge amount of investment in them and the fuel itself is energy rich, not overly expensive and plentiful. Then, if that is true, how better would it be to rather than vilify it and its use and demand its end, just accept that it is a part of the existing make up of world energy needs and deal with it. The power plants themselves can be made more efficient and cleaner burning, of course, but a real and fast solution to the emissions issue is the shift to what it emits. If the plants are “tweaked” towards a deliberate emitting of CO and NOx, rather than the more traditional desire to shift to CO₂ as it is less of a health risk when compared to the other two, then these could be captured and used in the combustion process(es). In the cases of power plants this could be done onsite for the increase of power generated from the same fuel. Or indeed NOx and CO can of course captured, stored and be sent off to be used elsewhere as a fuel/oxidiser, or again used onsite.

Having coal electricity power plants fed NOx/oxidiser/pure oxygen rather than using regular air would result in a much cleaner burn of fuel and efficiencies would be noticeable. As such less coal will need to be burned in the first place and therefore the price of the coal will be reduced.

The capture of the emissions and the admission that they exist and can be dealt with has another function. The capture of all of the emitted gases and the willingness to deal with them gives the opportunity to use the CO₂ as well. CO₂ has many uses and as has been seen during the recent fuel crisis it is major component in many processes, from food preservation to water treatment to fertilizer to plastics and polymers. The list of uses for CO₂ is vast and wide. If GG is initiated rather than worrying about emissions then these emissions become a boon to be used and a valuable product as well. The CO₂ saved from coal power stations could go on to replace CO₂ from other sources and thereby reduce costs of finding it form other sources. If the CO₂ can be separated off (which it can quite simply by the use of water and a “scrubber” or similar process) then the CO₂ becomes a distinct and clean stream and can be then used as a marketable product. As the burning of coal fuel is more efficient with the addition of the oxidizers into the process, then too will there be less CO₂ emitted in total so the value of the clean CO₂ will hold and be worth processing.

As the emissions would now dealt with in a proactive way then, there are other positive effects. The need to cast the emissions up and into the atmosphere as far away as possible requires a degree of inefficiency in the system. The emissions often take with them reasonable amount of heat to create the “loft” needed to rise them up and away. This heat could thus be retained and used in the overall energy production systems making the fuel burned even more potent. If the emissions are dealt with (power8ion) then: more heat can be retained and used in electricity generation and area heating; CO₂ becomes a resource to be traded and sold; NOx and CO can both be fed into the energy system at various points, and has a value and marketability; the harmful effects of acid rain and the consequent drag on agricultural production can be avoided; as NOx and CO have a negative effect on human heath and are being currently emitted, on a vast scale, then there is a risk of legal action for compensation if these are known about and continued—their capture, and indeed ramping up of their creation to capture more of it for use, would remove the liability that is created by their emission.

By capturing the exhaust/emissions of coal fired generation there is a useful byproduct. As these emissions are cooled it presents and opportunity to also capture the heavy metals and other pollutants that are contained within the “smoke”. These themselves are in some cases incredibly harmful—but have real uses if captured. The types of products captured would be mercury, arsenic, lead, cadmium and uranium—these all have uses and values so could, if captured via this system, be then sold on.

Biomass as a replacement to the burning of coal has been widely introduced over the recent past and is seen as by far the greener option as it has a “green feedstock”. This has been proved to be less accurate than it seemed. The areas used for this biomass production/growth are not overly productive or wildlife rich and the emissions are shockingly higher than the coal it replaces as the fuel (biomass) is less energy dense than the original coal. It is therefore a desired embodiment that these plants be retrofitted with GG systems to not only tweak emissions towards NOx and CO production and capture, but also have their combustion systems/chambers function with the addition of dedicated flows of NOx, oxidizers, CO or oxygen rather than just air. These embodiments will offset the wastes inherent in biomass use over coal. Home/building heating systems would be another desired embodiment of the GG system and the capture of their emissions and feeding of them with gas oxygen richer than standard air. There will be a definite role for this dedicated NOx stream going into oil and gas fired electricity generation plants also. With nearly 50% more available oxygen for burning than standard air it will have a welcome reception in the fuel stretched economy of the present—and the coming future.

There is another possibility in the GG system that bears specific mention. The creation of ozone by fossil fuel burning creates a significant “low level” (as opposed to low levels of) pollutant. It has many negative effects on humans and is linked to many deaths yearly. If, however, this ozone was captured at source/creation it could be then used, as there are many uses of it throughout industry, private and government circles—cleaning and water safety high on the list of uses. There is another possible use for this captured ozone, it could be with support of business, environmental scientists and governments taken up towards the holes in the “ozone layer” that have been caused by past pollution and deposited there to help heal the hole. Along with the great strides that have gone with stopping the use of chemicals and materials that harm the ozone layer, which should by no means stop and indeed there could be a “fine and deliver” with in the “Gredits System” for anyone found to be emitting theses substances, this could be a way of again taking a very negative waste emission and using it to good effect.

The acceptance of a situation and the rational viewing of it allows for positive outcomes, in this case there is a fuel crisis and there are emissions. Looked at together then the emissions can form a major part of the solution of the fuel crisis (with cleaner burning and higher output of energy from fuel burn) leading to a virtuous cycle towards a cleaner and greener blue planet.

### Gredits (Green Credits) (Shown in FIGS. 1/16)

A part of the GG system that will appeal to the potential user/government/company is the production of usable products like: water; electricity; hydrogen; oxygen; NOx; separated exhaust; and of course CO. All of which have a use and corresponding value.

The flip side to the use and conversion and capture of the exhaust is that there are no harmful emissions and that has a value too. There is a very large market in carbon trading and offsetting that deals specifically with this idea, changing the way someone does a task or job to reduce carbon emissions. These need monitoring to work and this is where the Gredits element comes into force. It would be a monitoring system to allow governments etc to be able to quantify the amount of “good” the system does. This in turn would allow businesses to see value and profit and therefore to invest and that in turn would allow customers or users a route to obtain GG and its benefits. If there is no quantifiable element to the system there isn't the security in the system and as this system is new it needs tangible “numbers” and an integrated monitoring system to chart every aspect of the systems “production” and its “savings” also.

### DESCRIPTION OF PICTURES

FIG. 1) Showing the GG mounted to a vehicle (old style vehicle to left with old style exhaust (4) then with CC removed on the right and the GG system with heat and exhaust capture (2) and (6) tanking and storage vessels with heat energy scavengers and converters/ATEG (8). Showing also the Pump and Dump collar system (3). Also noted is drip (free) end to pump handle (3/7). Wheel heat stripping and GGGP and energy transfer systems (9). BDS (10

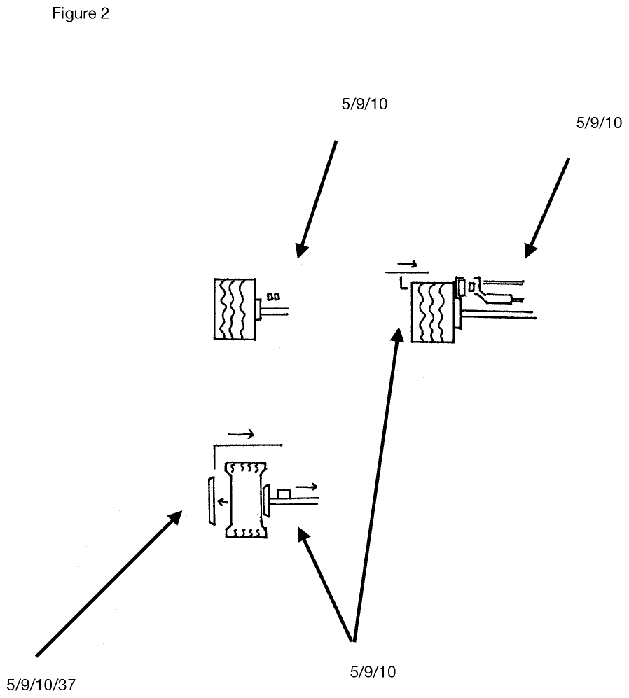

FIG. 2) BDS (10) system and GGGP (37) in place. Heat scavenging (9) and filters (10) also shown is Eleven Series (5).

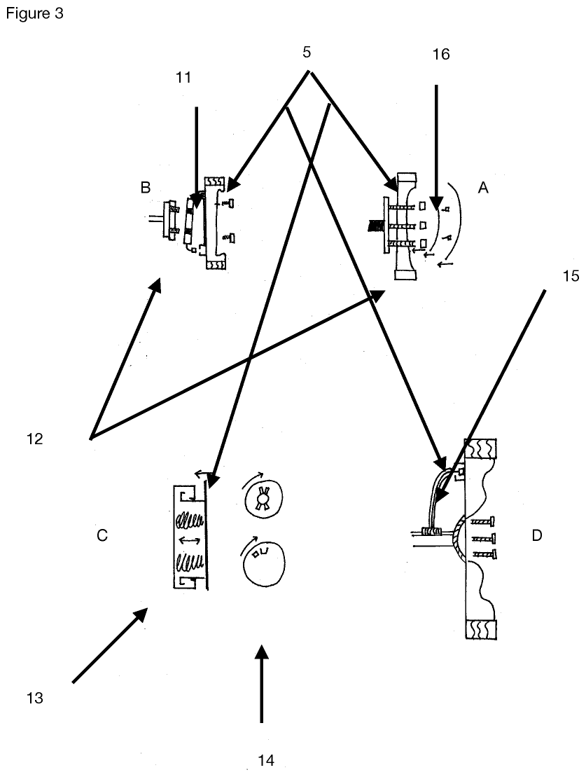

FIG. 3) Showing the Eleven Series (5) with embodiments including at A “Snub Cap” with secondary or functional cap (16); at B “CW Sandwich” with sandwiched coil in place (11); at C “Spring Keyling” with springs and push-in locking mechanism (13) with key locking (14); and at D “Power Takeoff” with tether arm and interaction mechanism (15).

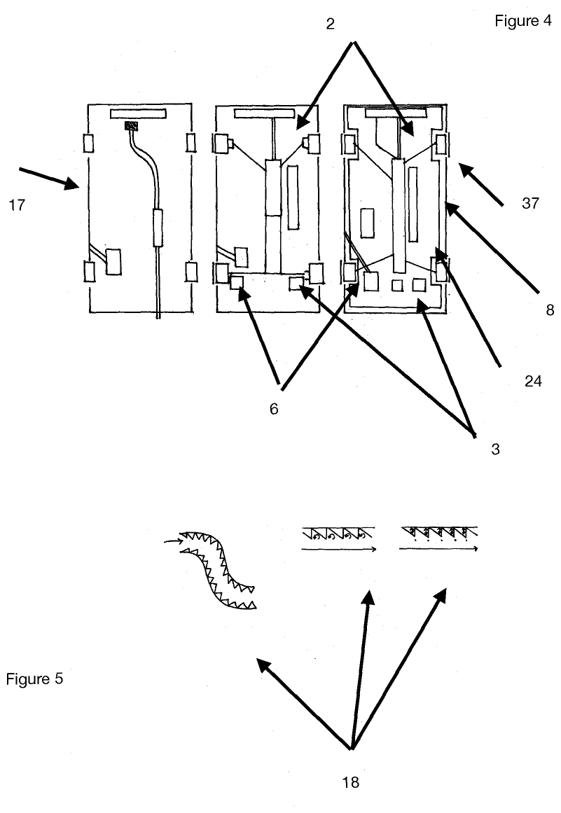

FIG. 4) Showing a old style vehicle to the left (17) a vehicle fitted with GG (2), centre, and a vehicle (right) fitted with GG (2) and (24) evaporation and undercarriage mounted steam generators and plate heat harvesting (8) etc. GGGP (37) and Eleven Series. Showing also the Pump and Dump collar system (3).

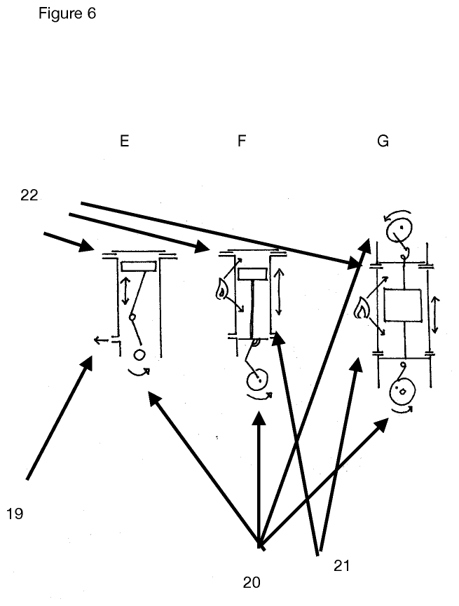

FIG. 5) Showing Dragon Tail (18) evaporative enhancements and also showing eddy and extended evaporation locations and air intakes.

FIG. 6) Showing variously the SEAICE (E) style of piston the Bangbang piston (F) and also the Double Header Crosshead Piston (G). With vacuum keeping port (19) with crankshaft or flywheel or similar connection (20) with secondary firing chamber to the rear of piston inc new fuel/exhaust ports (21) and with traditional fuel/exhaust ports (22).

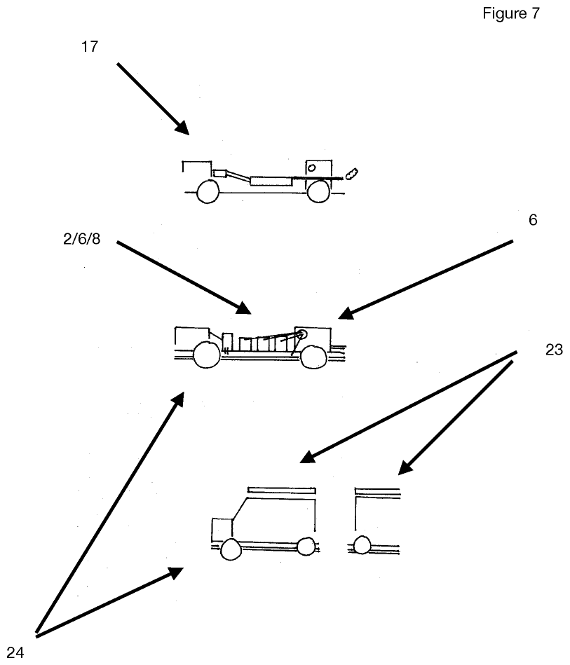

FIG. 7) Showing side view of conventional vehicle (17) and vehicles and trailer fitted with GG (2/6/8) under-mount evaporation system and heat converters (24). Solar panels and heat stripping to the roof with evaporation system to the underside of these (23).

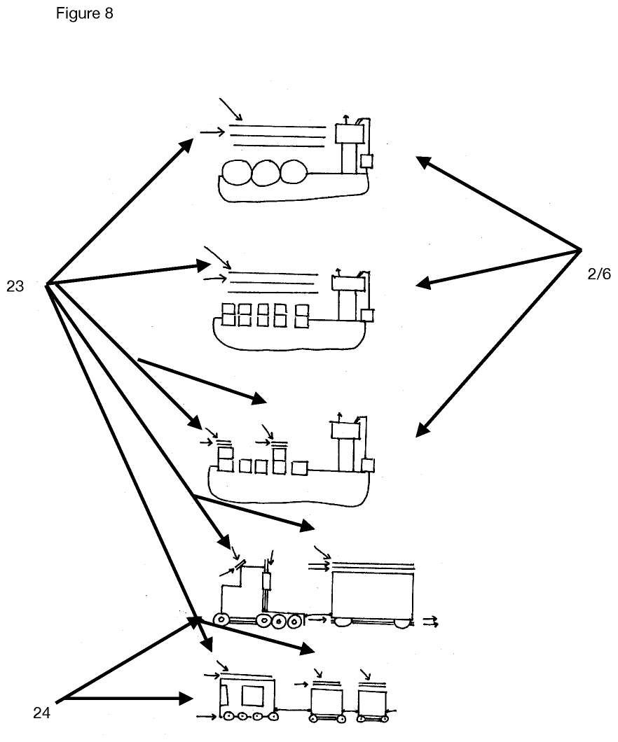

FIG. 8) Showing solar panels with heat stripping and evaporation system fitted to the rear of these (23) in various locations LNG ship/container ship/truck/train with system fitted also to individual containers for versatility. Ships and vehicles fitted with exhaust capturing element of GG (2/6). Under-mount heat conversion and evaporation system (24)

FIG. 9) Showing conventional fire with chimney next to “Fire's Place” system of exhaust and heat capture (25). Creosote condensation and burn off element (27/28). Safety bypass (27) and air exchange and room air burn functions (29). Pipework for exhaust removal and Fire's Place in situ (28).

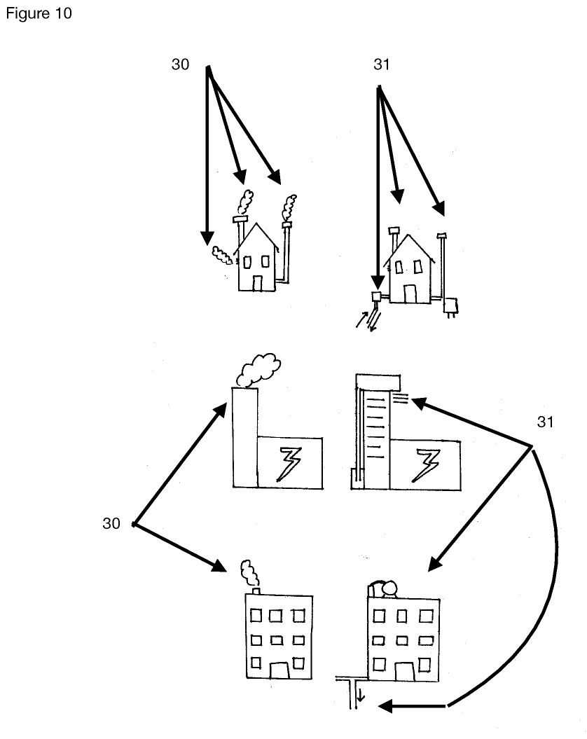

FIG. 10) Showing standard house power station and factory/building to the left (30) and those then fitted with GG functions (31). Pipes (tanking) away showing route for emissions to travel to treatment (31).

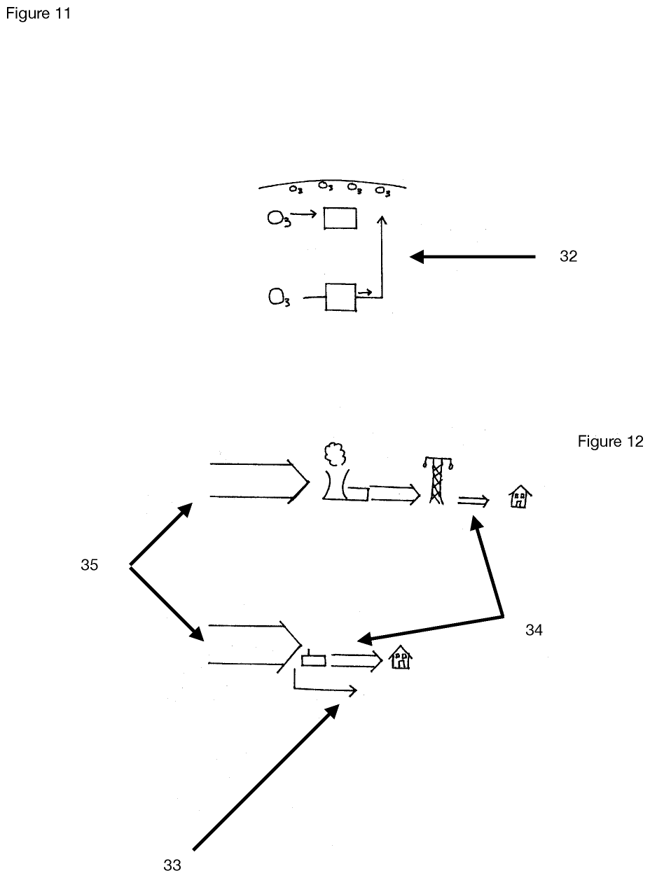

FIG. 11) Showing the capture of ozone that is being emitted at ground level, often by combustion of fuels, and how if this is captured at source as part of the GG system this can then be used as a resource onto open market. Also showing, perhaps of more importance, the captured ozone being taken up to the ozone layer to be used as a repairing material (32).

FIG. 12) Showing the embedded energy input (35) and routes to end user and the losses within that (34). Also showing the heating element fo Local Motion with its heat energy conversion to usable energy (inc electrical) and also standard heat delivery (33).

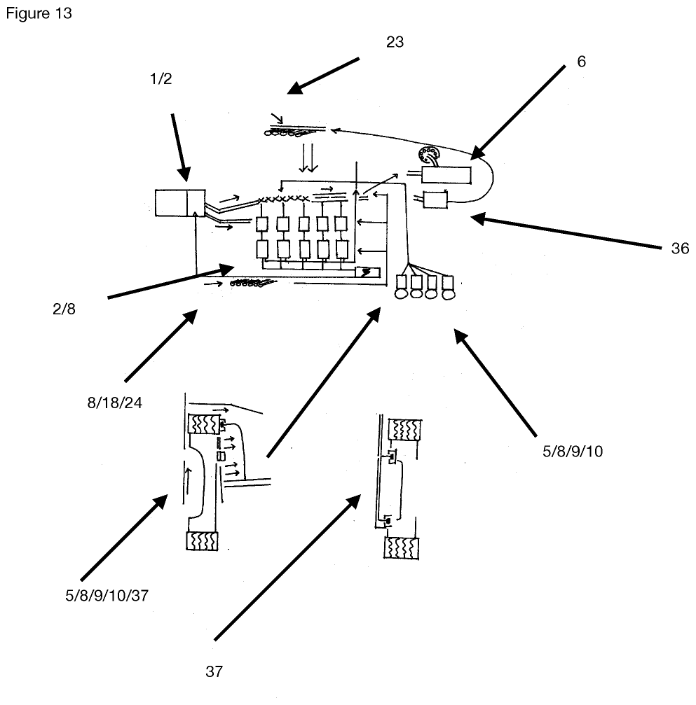

FIG. 13) Showing elements of GG system in interaction and use. ICE engine and GG linkage (1/2) and heat stripping and GG (2/8). Storage tanks for NOx/CO and the like (6) with water tankage and interaction captured from exhaust and used within the system at various places and for various uses (36). Wheel/trye area upgrades (5/8/9/10/37). Under-mount evaporation cooling system and interaction with GG (8/18/24) also overhead solar panels cooled and separate evaporative cooling system both with possible interaction with GG system in thermoelectric generation.

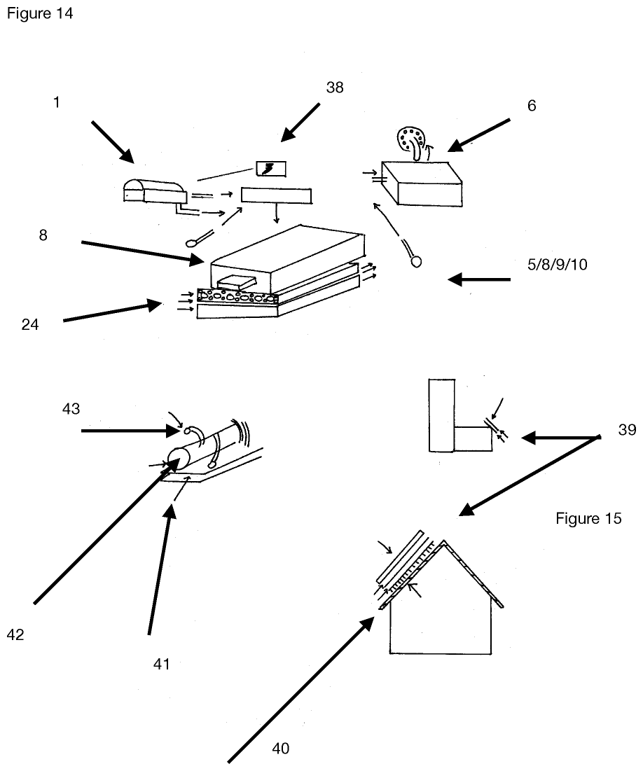

FIG. 14) Showing various elements of the GG system in interaction. ICE (1) battery storage (38) storage tanks (6) Under-mount evaporative cooling and steam generation system and heat harvesting (8/24). Heat sources and wheel upgrades (5/8/9/10). Evaporative cooling and cooling pipe elements including plate cooling (41) and straight pipe (42) with helix/double helix/or more helix shown in wrap around format for extra cooling effect (43). Solar panels fitted with evaporative cooling function (39) also showing building cooling via an evaporative cooling system (40).

FIG. 15) Showing (39) solar panels fitted to various building locations with cooling function with or without additional evaporative cooling method. (40) showing building cooling with or without interaction with solar panel cooling, with or without heat harvesting from these. Cooling of buildings via (40) evaporative cooling and/or also using the Dragon Tail evaporative cooling device. Heat harvesting from building and/or solar panels via heat accumulation for use.

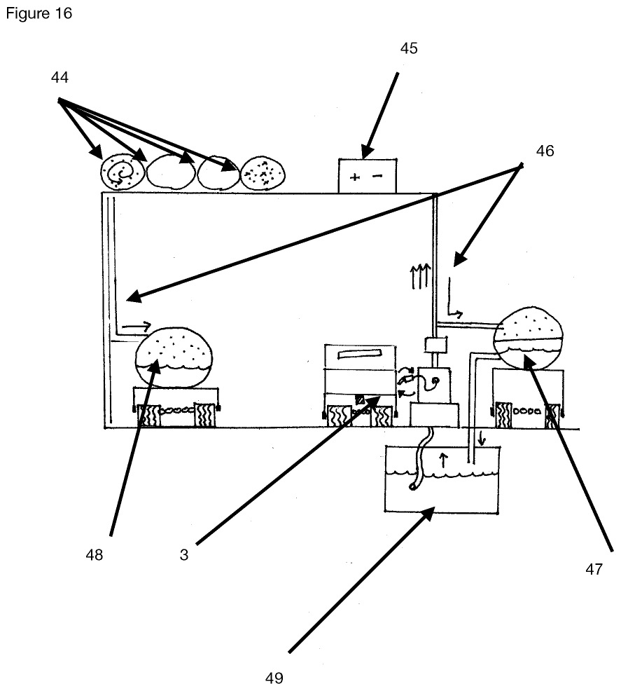

FIG. 16) Showing a possible forecourt example using the GG system and vehicles fitted with GG (3) and also some of the functions involved with the transport/movement/Gredit interactions. Tanks fitted to the roof or similar (44) and electric storage (45) with piping to and fro the vehicles, tanks and delivery vehicles (direct piping is of course possible) (46). Delivery vehicle fitted with tank separation (47) and vehicle allowing the transit of GG materials within the confines of the tank (48). Storage of the GG materials within the existing fuel tanking system with GG pipework.

It will be apparent and clear to those skilled in the art(s) that the subject technology is not limited to the specific details set forth herein and indeed the invention may encompass a variety of forms that may be similar to or different from the embodiments set forth.

What is claimed is:

1. An active resource harvesting system comprising a tank arranged to accept in emissions/exhaust/effluent from a system or device where the burning of hydrocarbons, volatile hydrocarbons and/or fixed carbon occurs and in which the emissions/exhaust/effluent would conventionally be regarded as an undesired waste product and arranged to discharge the emissions/exhaust/effluent for use as a feedstock in another useful process/processes (other than merely trying to sequester, discard or destroy etc), with means to separate the emissions/exhaust/effluent into constituent/useful parts at source and/or at a remote location for use of the emissions/exhaust/effluent, the system is arranged to feed the harvest of emissions/exhaust/effluent along exhaust stream to the tank/tanks.

2. Further to claim 1 tanks for the storage onboard vehicles of emissions from the combustion of fuel for transfer later, often at refuelling though home or at building “dumping” is possible provided there is a piping system for this, these being targeted initially in—the space of the now defunct muffler and exhaust/the defunct (or reduced) radiator/the underside of the vehicle/the internal body framework/fuel tank sharing (with separation systems if needed); systems for the separation of exhaust into its constituent parts where convenient and economic; “swap-out” tanks that can be filled and then simply swapped out with empties when needed; “easy swap out batteries” for similar swap system to the filled gas tanks, but with batteries filled with usable energy; out storage tanks above and below for the storage of said exhaust (or direct pipework where practical) for transfer on to refineries or indeed refining on site, these being from fuel station/office/home/carpark/factory or similar; creation of pressurized gases onboard a vehicle (inc the pressurization of exhaust) as a form of stored energy onboard; use of this created pressurised gas onboard to offset running (fuel usage) cost.

3. Further to claim 1 “Smart Collar” (SM) system that can not only house monitoring systems for onboard calibration and definition but also transmit this data to desired other locations for verification and processing purposes, but also provide a locking element safety system (if desired) so that fuel can only be pumped when a locked and safe situation is presented; also this system would have the function of ensuring that only the correct fuel is placed into the vehicle by either computer control and monitoring or by the more simple function of different shaped heads/pipes/nozzles so only the correct format of fuel can be pumped into the vehicle; the SM system would also be capable if needed of allowing other products to flow in or indeed out (or going either way) of the vehicle for increased efficiency and other use (under the name of “Pump and Dump” element)—these are noted, but not limited to, NOx/electricity/O/CO/gas/pressurized gas(es)/liquid hydrocarbons (natural or manmade)/water/all onboard gases and fluids maintained (eg brake fluids, oils, coolant, window washer fluid, etc) to a correct and safe level/ammonia; spill or “drip-free” end added to pump handle to ensure that the fuel doesn't drip from the end of the hose at end of fill (inc partial cover and fully closing ending); spark reduction designs to the pump handle including spark-free coatings/sleeves and active grounding design and control system with static electricity grounding routes/lines (built into handle, pumps and pipelines); additional lines added to the pump handle and pumping lines to accommodate further streams of material (beyond fuel on way or a format of fuel and CO₂).

4. Further to claim 1 fuel vapour collection and harvest/conversion/condensation/accounting system to ensure all fuel is used not lost into the atmosphere as waste and pollution (the fuel vapour is after all the part of the fuel that is used for combustion); fuel vapour capture/condensation as drawn out (or pushed) with the air during the filling process.

5. Further to claim 1 tanker/fuel truck/truck/vehicle/vessel modifications to allow “back-hauls” of the exhaust/gases/products of this system to refineries or conversion sites or discharge pipe connection site; pipework and tanking systems to allow this backhauling to occur in a safe fashion;
pressurized gas systems for energy storage using a similar function;
pressurized gas from this system used directly onboard for fuel use reduction or transferring out for “Gredits” /alternative use; full or semi full undercarriage of heat harvesting and conversion systems with lift kit system to allow fitting to any type of vehicle; undercarriage evaporative cooling system; roof and over vehicle evaporative cooling system—with linkage to heat systems where needed for the creation of thermoelectric generation.

6. Further to claim 1 CC removal or replacement to make way for a system to give the correct “draw” to the engine for best fuel use; CC removal and exhaust capture and exhaust alteration and capture to push said exhaust towards NOx and CO production and account these; CC removal for the “back-pressure” release to the engine and efficiency gains so created—using a CC stops the engine venting its exhaust in a manner that is best for fuel efficiency removing the CC therefore means a more efficient use of fuel—capturing the exhaust gives the same or better results with better fuel consumption; if a full GG system isn't installed a tanking in its stead (or in the mean time) to capture the “un-CCed” gases, and accounting of these, from before CC warms to correct operating temperature (as opposed to what currently happens whereby the gases are made to simply bypass the CC and dumped direct into the atmosphere—it would be worth doing as by far the most harmful emission producing time in the (even modern) engines cycle is at start up, the only point where the CC is not functional); a post CC tank to function even when the majority of the emissions are with only a minor amount of the desired NOx and CO created as their use is so worthwhile (and emission so harmful) as to make it viable (with captured CO₂ for use where needed as a commodity—with the very clear exception of CO₂ for the creation of alternative fuels made of CO₂); unburned or CC destroyed hydrocarbons within the exhaust held/pushed into ammonia production; production using CO captured and exhaust heat for the production of liquid hydrocarbon/syngas using where needed hydrogen; exhaust heat used as separating power source for exhaust gases.

7. Further to claim 1 combined heating power (CHS) systems for the accumulation of the varied and disparate heat sources within the function of vehicles and engine operation (ICE engines using conventional fossil fuels and also including heat generated via hydrogen supplied engines or other heat emitting engines/devices including jet engines) with major heat contributions for combining coming from engine combustion exhaust/engine cooling/vehicle body and bodywork cooling/“A/C” heat dumping and heat pumping/solar panel cooling/wheel cooling/tyre cooling/tyre friction heat harvest/braking cooling/air surrounding brakes cooling;
“cluster bases” of automotive thermoelectric generator (ATEG) whereby many of these are fitted across the base of the vehicle (perhaps in a factory made “total base”) and facilitated with the addition of a “lift kit” if so needed; ATEG and evaporative cooling systems tied onboard vehicles for best energy use; ATEG in sequence whereby flows of heated material (exhaust, CHS fluids/gases) are sent through ATEG after ATEG of correct (varying if necessary) sizes in order to extract maximum energy—often in combination with plate heat exchangers for best energy from exhaust/CHS removal and channeling; cooling pipes with standard versions that simply use rushing past air to cool (vehicle interiors, containers, trucks, trailers, vans, ships [inc cargo] etc) or more advanced types that hook into the CHS system to provide higher temperature differential to run thermoelectric generators—with or without evaporative cooling efficiency increasing sub system; shock absorption energy harvesting subsystems including those that use heat as the transfer method (drawing this into the CHS or similar), and/or creation of pressure for use within the vehicle for energy harvest or creation or sent off vehicle for use elsewhere, or electrical generation via movement harnessing; computer (inc data center or server center) cooling via CHS subsystem that causes the heat to be drawn in and then placed towards energy harvesting systems, accumulated or used directly, with the intention of reducing the overall energy use or increasing efficiency; evaporative cooling system applied to the cooling of computers; conversion of exhaust waste heat from engine and CHS into pressurised gases; ammonia production from use of CHS system; syngas (or similar) production with use of CHS.

8. Further to claim 1 use of multi-stage and device heat harvest and conversion systems to gain maximum heat retention for use within the generation system and then once captured maximum energy conversion and use; use of combinations of HTE/steam electric generation/phase shift of gas and fluid/heat pump/thermoelectric generation/thermoelectric generation with attached evaporative cooling for maximum effect (temperature difference)/automotive thermoelectric generator (ATEG)/integrated multi-layered steam electric generators (including full base undercarriage bolt on type); heat storage on board and transfer systems for delivery of unused/remaining heat for further use; use of the above mentioned systems to contribute to the production hydrogen and oxygen, with option to take the H to form part of ammonia as a stable and useful energy storage method; use of above to encourage the production of NOx and CO from exhaust stream rather than allowing gases to form into CO₂; these systems applied to the cooling of computers and servers with accumulation (or direct use) of heat and direction of heat through these for the generation of usable energy.

9. Further to claim 1 CO capture and use onboard with above to mix with H and metal catalyst and heat to reform into liquid hydrocarbons; use of above to take unburnt hydrocarbons in exhaust stream and reforming these with the products of water cracking to create ammonia;

10. Further to claim 1 capture, separation and storage ability of multiple types of gaseous emissions with ability to deliver these off vehicle for further use with accounting system to assess these.

11. Further to claim 1 solar electricity generation panel cooling and consequent heat accumulation and harvesting for not only better function of solar panels but also for electricity production (beyond the existing solar generation) from the heat (inc steam generation); with hot water generation from this panel cooling function; water purification from this stripped heat; water desalination from this heat.

12. Further to claim 1 a series of interlinked systems to trap/capture/stick brake dust and remove its harmful effects on the atmosphere and those within it; with disposable and self cleaning options to magnetically remove or otherwise stop their release into the air in general; of real and specific relevance to vehicles operated indoors (or in tunnels—tubes and metros for example) but equally relevant to above ground vehicles such as trucks/cars/vans/trains/planes; with portions that can be fitted to fore and rear of wheel and braking system and other systems that can strip away air for filtration (and heat for use with in the CHS or other such braking energy harvest); heat stripping from wheels and tyres to be included within the CHS system and giving better control of tyre and wheel with improved operation and running; retro-fitting and new build versions of said systems; tyre heat stripping and ability to draw said heat into the CHS or similar system for active use of heat and best use of tyres (reduced wear and improved operation); heat addition to the tyres/wheels for best operation in cold weather and the like; GG Great Plates for the housing of filtration and magnetic brake dust capture and heat stripping from wheel/tyre and interaction with wheel rotation to create/capture usable energy (especially electrical) also pressure creation—in addition to the aerodynamic flow increase and the wheel arch air flow capture elements—swing or slide out of the way functions for wheel/brake/GG etc access; automatic BDS system cleaning or filter wash, home/self clean or commercial version; filtration of particles emitted into the atmosphere by the use of tyres, these drawn on board and run through filtration systems for management of particulate and emissions (including out routes though GG or changed filters); use of these systems on wheels without brakes.

13. Further to claim 1 “Eleven Series” safety and energy generation systems including: firstly a secondary or functional safety hubcap with direct linkage to the axel stub (with possible key); secondly a coiled wire tether that is housed between the rim and the axel stub to stop wheel escape; thirdly a spring-loaded locking mechanism that once pressed in and twisted will push the rim back outwards locking it from flying loose of the vehicle (with possible key); and fourthly one that is attached to the axel housing (and/or vehicle body) providing another location for a tether type safety device but also one that can be used in speed control (braking, emergency or other) or the generation of pressure, heat and/or electricity; dedicated types of the fourth with only (or combined) pressure, speed, heat or electricity generation functions; key/lock system to secure the rim to the axel (or 11 series which is also secured to the axel/vehicle body).

14. Further to claim 1 “SEAICE” system of vacuum creation to the rear of pistons to create a space for the piston to without resistance travel away from the explosive force of the combustion within the chamber; systems of heat stripping (with accumulation into the CHS desired) in order to maintain desired operating temperature; hollow pistons to allow heat stripping action via flow through; linkage to a CHS style of system to allow use of heat stripped.

15. Further to claim 1 Bangbang Pistons and Double Header Crosshead Pistons to give a higher energy output from the already in use piston chambers; with the Bangbang piston looking like a regular piston however having a combustion chamber fitter to the “rear” of the piston; Double Header Crosshead Pistons looking like a double ended piston having compression chambers to either side to allow for high energy output and efficiency gains; piston heat take off systems to ensure correct operating temperature; vapour compression cycle used in heat stripping (also in the SEAICE version) for high efficiency heat stripping; high heat and high flow pumping systems for quick heat removal; pumping systems linked directly into the actual pumping actions of the pistons themselves; secondary set of intake and exhaust ports to piston chamber to allow double ended firing; linkage to CHS style of system to allow use of heat stripped.

16. Further to claim 1 water collection system to capture exhaust water for evaporative cooling systems that give efficiency increases and fuel use reductions (inc phase shifting of water for maximum energy harvest; evaporative cooling and “waste-heat” or excess heat (or already harnessed by CHS) onboard vehicle (boats/trains/ship/trucks/vans/cars etc) link up to enable thermoelectric generation; use of this collected water to feed into the water cracking via HTE; use of the onboard cracked water's H to feed into the creation of ammonia; excess water purified and/or heat treated for potability; bringing on board water to be run through the existing system of water purification; “Dragon Tail” increased surface area system to allow for greater evaporation or heat exchange or air/gas intake or the like through use of the shape and “eddies” created by that shape; evaporative cooling for use within computer scenarios including from personal computers (and smaller) to data centers; accumulation (or direct use) of this heat to create usable energy including electrical via steam generation or similar; solar shielded evaporative cooling system for the direct offsetting of cooling costs caused by the need to keep vehicles/cargo cool using other methods; linkage of solar PV and solar panels to a evaporative cooling system mounted beneath (thereby shielded from direct solar gain and focusing the heat stripping to desired zones); solar panels inc PV with evaporative cooling builtin to back.

17. Further to claim 1 solar panels with heat stripping functions inbuilt or retrofitted to allow for the best operation of solar PV panels; this heat could be applied to electricity generation or water purification or home heating or water heating in general or tying into systems of cooling (including evaporative cooling) for thermoelectric energy generation; evaporative cooling functions added to solar panels with direct use of cooling and electricity and fuel use offsetting (boats/containerships/CGN ships/trains/trucks/vehicles/vans; use of these solar panels with evaporative cooling function to also act as a sunshade to further reduce energy consumption; this can be combined with or run separately to a system of evaporative cooling that can be used in the cooling of buildings, power-stations, factories and vehicles etc also being able to create a sun shielding effect whilst creating a space or air gap to run evaporative cooling in—including specifically the “Dragon Tail” increased surface area element/the “Central Pipe” evaporative cooling elements including/the Double Helix Evaporative Cooling element (including its wrapping around the Central Pipe elements)/and “Plate Cooling” evaporative cooling function/or combinations of these for maximum effect.

18. Further to claim 1 “Fire's Place” logburner/fireplace/woodstove emission capture system and heat retention measures for increased efficiency and cleaner burning; specific particulate capture system dedicated to the eradication of as much of the deadly particulate that is emitted from the use of these devices (inc filtration and staged filtration); creosote condenser element to the device to force creosote to adhere to a surface within the device that can then be run through with high heat to efficiently burn off this otherwise wasted heat; capture of emissions from these devices (woodburners etc) retention, tanking, piping and delivery method (inc vehicles for said operations) for taking these emissions to a place of separation and use/sequestration; safety bypass system using chimney or like device to remove emissions to a safe level if malfunction/need occurs.

19. Further to claim 1 use of NOx/oxidiser/O/CO to increase the efficient burning of fuel in logburner/fireplace/woodstove devices via piping this directly into the burning chamber (with implied safety systems implemented) with connections to either local storage or indeed grid network; system in the absence of ready supply of NOx/oxidiser/O/CO (or for use in conjunction with) using a system of heat transfers to warm incoming fresh air into a building with “dirty” indoor air (that is rather than being dumped out making outside air dirtier is) instead fed into the combustion box of the fire—this warms the incoming air so there are no drafts and also efficiently “cleans” the indoor air with out polluting the outside any more than the original fire would and if the rest of the system is fitted no, or very little pollution, is emitted.

20. Further to claim 1 “LocalMotion” dedicated local appropriate sized electricity generation systems using NOx/oxidizer/O/CO as a feed stock (whether using SynGas, NatGas, Gas, oil or other fossil fuel or manmade alternative); with spent heat from this system captured and used as local area heating system and hot water source with any excess available to sell/use.

21. Further to claim 1 feedstock alteration for electric generation plants (specifically coal but with direct application and use towards gas, oil and biomass) changing from simply drawing in air for combustion towards using NOx/oxidizers/O/CO; direct delivery of NOx/oxidizers/O/CO to vehicles to replace the use of standard drawn in air—taken in at the same time as fuel, or when convenient/needed.

22. Further to claim 1 captured gases from exhaust stream (again from coal, gas, oil, biomass) now turned into usable products with a push towards the creation of NOx and CO in these streams; with NOx and CO already stripped out (captured) now the remaining CO₂ is taken out (further refined) also as a byproduct with salability; systems for the capture of minerals and metals that would otherwise be left to escape into the atmosphere and harvesting these materials for use and sale (heavy metals [including specific interests in the capture of mercury, arsenic, lead, cadmium and uranium] and other airborne toxins targeted specifically as these are not only useful but when sent into the atmosphere challenging to recapture and harmful).

23. Further to claim 1 use of the heat from the now captured exhaust for efficiency increases to overall systems (coal/gas/oil/biomass) as rather than losing air to remove emissions to height that heat can be retained within the overall system and put to other more productive use (local area heating, increasing power outputs, reduction of fuel use etc).

24. Further to claim 1 a fully rounded system of emission control (from the burning of fuels) with specific interest in ozone capture for the betterment of low level air conditions and the reduction of harmful emissions and their endangerment of the population; these captured ozone emissions are then fed into the open market for ozone (with consequent reduction in manufactured ozone and emissions relating to said operation), with a targeted partial aim of water purification; excess, or desired, ozone is also to be accumulated and then sent upwards (by various means) towards areas of man made or natural ozone depletion within the “Ozone Layer” to repair the damage to it by the addition of said ozone for use as a repair building material (rather than only waiting for or relying on natural regeneration).

25. Further to claim 1 “Gredits” system (computerized) of monitoring and quantification of products created and also unreleased emissions across the various embodiments of the system and interaction systems for human/government/corporate interface and interaction for offsets, payments and accreditation—with trading system and accounting software to ensure accurate and reliable results that give confidence in the overall system that can be accessed and relied upon by governmental and intra-national organizations and also with ability for international and trans-country groups; also including a safety systems and warning systems/devices/sirens etc in relation to all of the above mentioned points/elements.
